(19) United States
(12) Patent Application Publication
(10) Pub. No.: US 2026/0371720 A1
(43) Pub. Date: Nov. 19, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Fu-Ting Yen, Hsinchu City (TW); Yu-Yun Peng, Hsinchu (TW); Winnie Victoria Wei-Ning Chen, Hsinchu County (TW)

(73) Assignee: Taiwan Semiconductor Manufacturing Company, Ltd., Hsinchu (TW)

(21) Appl. No.: 19/212,534

(22) Filed: May 19, 2025

(51) Int. Cl. H10D 84/85; H10D 84/01

(52) U.S. Cl. CPC H10D 84/852; H10D 84/017; H10D 84/0188

(57) ABSTRACT

A semiconductor device and method of forming the same are provided. Dummy gate dielectrics are formed on sidewalls of first and second fin structures. An opening is formed to reveal facing sidewalls of the first and second fin structures. Protection layers are formed on the facing sidewalls. A dielectric liner layer is formed to cover the protection layer. A dielectric block is formed in the opening and enclosed by the dielectric liner layer. The dummy gate dielectrics and the protection layers are removed to form recesses revealing the facing sidewalls of the first and second fin structures. A separation structure is formed by removing portions of the dielectric liner layer to widen the recesses. A first gate electrode and a second gate electrode are formed in the widened recesses and on the first and second fin structures respectively, and are separated to each other by the separation structure.

### BACKGROUND

To improve the integration density of various electronic components (e.g., transistors, diodes, resistors, capacitors, etc.), the reduction of minimum feature size are being researched and implemented. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 15 are schematic cross-sectional views and top views schematically illustrate various stages of a process for forming a semiconductor device in accordance with some embodiments of the present disclosure.

Referring to FIG. 16 to FIG. 17, flowcharts illustrate processing steps of a process for forming a semiconductor device in accordance with some embodiments of the present disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device and a method of forming the semiconductor device are provided. A dummy gate dielectric sandwiched between gate spacers is formed on inner and outer sidewalls of first and second fin structures. An opening is formed to reveals the inner sidewalls (e.g. the facing sidewalls) of first and second fin structures. Protection layers are formed on the facing sidewalls of the first and second fin structure and sandwiched between the gate spacers. A dielectric liner layer is formed on the protection layer and the gate spacers. A dielectric block is formed within the opening and enclosed by the dielectric liner layer. Due to the material differences, the dummy gate dielectric and the protection layer are removed by different etching steps to form recesses revealing the facing sidewalls of the first and second fin structures. A separation structure is formed by removing portions of the dielectric liner layer to widen the recesses. First and second gate electrodes are formed in the widened recesses and on the first and second fin structures respectively. The separation structure physically and electrically separates the first gate electrode and the second gate electrode.

The facing sidewalls of the first and second fin structures protected by the protection layer remain a greater lateral dimension of the dielectric liner layer on the gate spacers in the subsequent processes, relative to the inner sidewalls not covered by the protection layer (e.g. covered by the dummy gate dielectric). The semiconductor device including the separation structure with the greater lateral dimension improves the gate control performance, the switch speed and improve alternating current (AC) performance. The semiconductor device also improves the controllability of the silicon (channel) sheet formation of the first and second fin structures. As a result, the performance of the semiconductor device is improved.

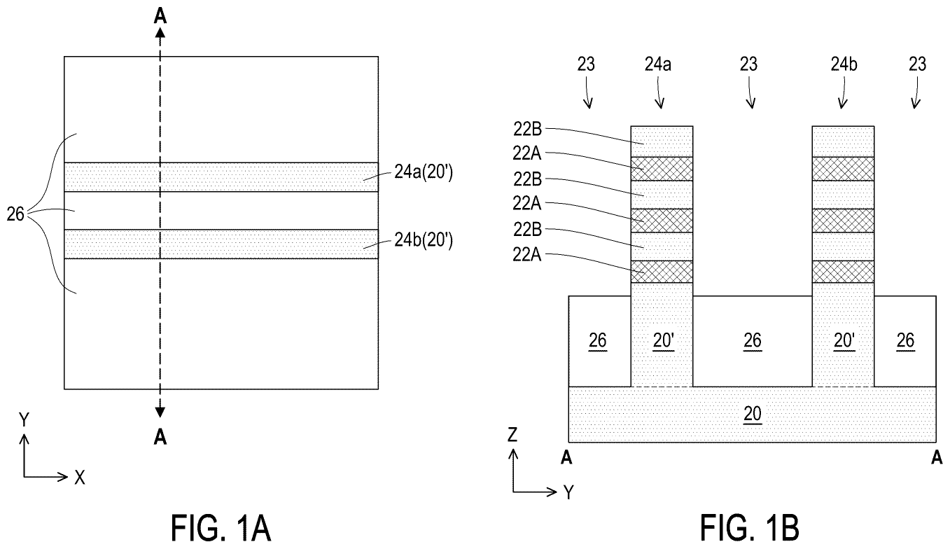

FIG. 1A through FIG. 15 are schematic cross-sectional views and top views schematically illustrate various stages of a process for forming a semiconductor device in accordance with some embodiments of the present disclosure.

Referring to FIG. 1A and FIG. 1B, FIG. 1A is a schematic top view of the structure, and FIG. 1B illustrates the schematic cross-sectional view along the cross-sectional line A-A in FIG. 1A. In some embodiments, a substrate 20 is provided. In some embodiments, the substrate 20 is a semiconductor substrate. For example, semiconductor substrate includes a silicon substrate, a silicon germanium (SiGe) substrate, or the like, while other substrates and/or structures, such as semiconductor-on-insulator (SOI), strained SOI, silicon germanium on insulator, or the like, could be used. In some embodiments, the substrate 20 is doped as a p-type semiconductor. In some embodiments, the substrate 20 is doped as an n-type semiconductor.

Referring to FIG. 1A and FIG. 1B, before protruding fins 20′ and shallow trench isolation (STI) regions 26 are formed, first semiconductor layers 22A and second semiconductor layers 22B are alternately stacked on the substrate 20 and form a multilayer on the substrate 20. Then, photolithography processes are performed to form the protruding fins 20′ protruding from the substrate 20, first and second fin structures 24a, 24b on the protruding fins 20′, and trenches 23 shown in FIG. 1B.

In FIG. 1A, each strip of the first and second fin structures 24a, 24b and the underlying protruding fins 20′ extends along a first direction (e.g. X-direction), and is separated from each other in a second direction (e.g. Y-direction). The second direction is perpendicular to the first direction.

In FIG. 1B, the first and second fin structures 24a, 24b each includes the first semiconductor layers 22A and the second semiconductor layers 22B alternative stacked to each other in a third direction (e.g. Z-direction). The third direction (e.g. Z-direction) are perpendicular to the first and second directions. Trenches 23 are also formed, one of the trenches 23 is formed between the first and second fin structures 24a, 24b and the adjacent protruding fins 20′. In some embodiments, lowest first semiconductor layers 22A of the first and second fin structures 24a, 24b are formed on and in contact with the corresponding protruding fins 20'.

In some embodiments, the first semiconductor layers 22A (referred to as sacrificial layers) are formed of a first semiconductor material, and the second semiconductor layers 22B, functioning as channel layers, are formed of a second semiconductor material different from the first semiconductor material. In some embodiments, the first semiconductor material of the first semiconductor layers 22A is or includes silicon germanium (SiGe), germanium (Ge), silicon (Si), gallium arsenide (GaAs), indium antimonide (InSb), gallium antimonide (GaSb), indium aluminium arsenide (InAlAs), indium gallium arsenide (InGaAs), gallium antimonide phosphide (GaSbP), gallium arsenide antimonide (GaAsSb), or the like. In some embodiments, the first semiconductor layers 22A (for example, SiGe) are formed through any suitable epitaxial growth process.

In some embodiments, once the first semiconductor layer 22A has been formed over substrate 20, a second semiconductor layer 22B is formed on the first semiconductor layer 22A, and the first semiconductor layers 22A and the second semiconductor layers 22B are sequentially formed and stacked in alternation. In some embodiments, the second semiconductor layers 22B are formed of or include the second semiconductor material such as Si, SiGe, Ge, GaAs, InSb, GaSb, InAlAs, InGaAs, GaSbP, GaAsSb, or combinations thereof. In some embodiments, the second semiconductor layers 22B (for example, crystalline silicon) are formed through any suitable epitaxial growth process. The second semiconductor material is different from the first semiconductor material of first semiconductor layers 22A. In some embodiments, the first semiconductor layer 22A includes silicon germanium, the second semiconductor layer 22B includes crystalline silicon.

In some embodiments, the second semiconductor layer 22B is epitaxially grown on the first semiconductor layer 22A using a deposition technique similar to that is used to form the first semiconductor layer 22A. In some embodiments, the second semiconductor layer 22B is formed to a similar thickness to that of the first semiconductor layer 22A. In some embodiments, the second semiconductor layer 22B may also be formed to a thickness that is different from the first semiconductor layer 22A.

In some embodiments, the shallow trench isolation (STI) regions 26 are formed on the substrate 20, and are disposed beside and wrap the protruding fins 20′. In some embodiments, the STI regions 26 include a dielectric material. For example, the dielectric material is formed by using flowable chemical vapor deposition (FCVD), spin-on coating, high density plasma chemical vapor deposition (HDPCVD), or the like. In some embodiments, a planarization process such as a chemical mechanical polish (CMP) process or a mechanical grinding process may then be performed to level the top surface of the dielectric material, and the remaining portions of the dielectric material are the STI regions 26.

The STI regions 26 are then recessed, so that the first and second fin structures 24a, 24b and tops of protruding fins 20′ are revealed, shown in FIG. 1B. The adjacent protruding fins 20′ are isolated from each other by the STI regions 26. In some embodiments, the recessing of STI regions 26 is performed through a dry etching process. For example, NF₃ and NH₃ are used as the etching gases. During the etching process, plasma may be generated. Argon may also be included. In alternative embodiments, the recessing of STI regions 26 is performed through a wet etching process. For example, the etching chemical includes HF.

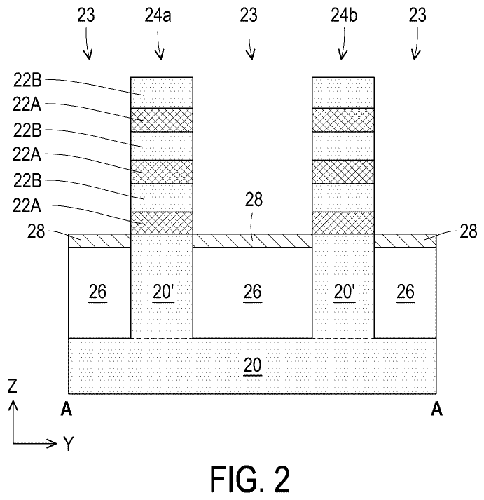

Referring to FIG. 2, FIG. 2 illustrates the schematic cross-sectional view. In some embodiments, a hard mask layer 28 is formed on the STI regions 26 and covers the revealed protruding fins 20′. In some embodiments, the hard mask layer 28 is levelled with the protruding fins 20′. For example, a material of the hard mask layer 28 includes silicon nitride (SiN). In some embodiments, the hard mask layer 28 is formed by a chemical vapor deposition (CVD) process such as plasma-enhanced chemical vapor deposition (PECVD). The hard mask layer 28 may protect the STI regions 26 in the subsequent process.

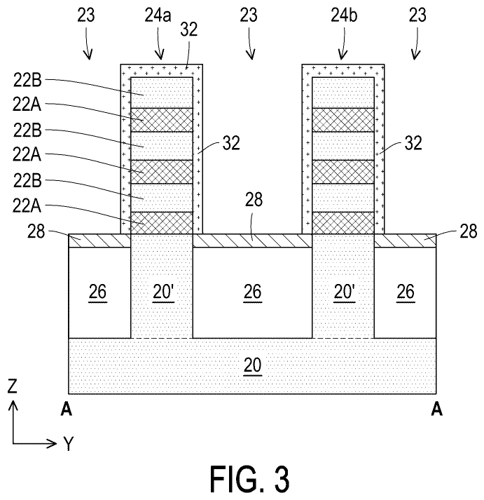

Referring to FIG. 3, FIG. 3 illustrates the schematic cross-sectional view. In some embodiments, dummy gate dielectrics 32 are formed on top surfaces and sidewalls of the first and second fin structures 24a, 24b. In some embodiments, a material of the dummy gate dielectrics 32 includes such as an oxide material such as a silicon oxide, silicon oxynitride (SiON), a combination thereof, or the like. In some embodiments, the dummy gate dielectrics 32 are formed by oxidizing the surface portions of the first and second fin structures 24a, 24b and the protruding fins 20′ to form oxide layers, or are formed by depositing the oxide layers.

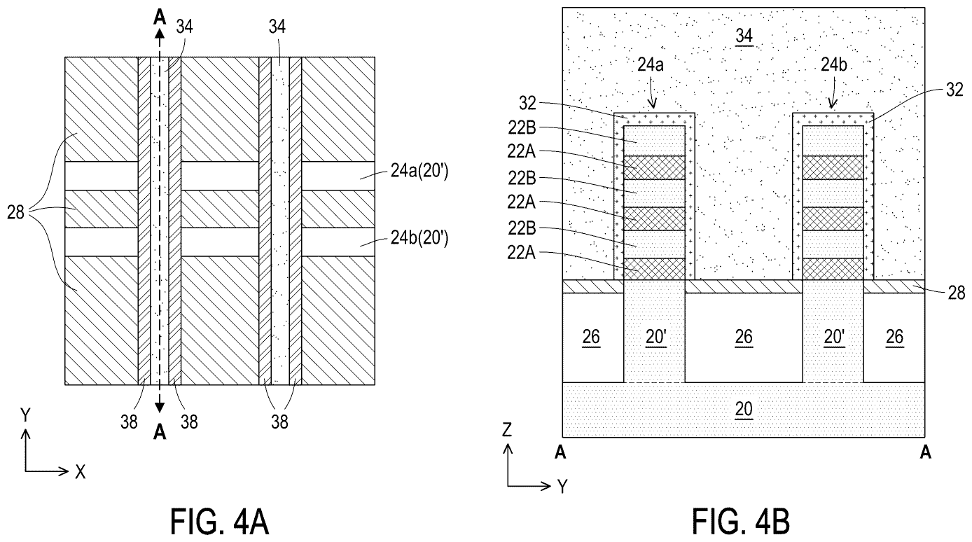

Referring to FIG. 4A and FIG. 4B, FIG. 4A is a schematic t view of the structure,, and FIG. 4B illustrates the schematic cross-sectional view along the cross-sectional line A-A in FIG. 4A. In some embodiments, the dummy gate structures 34 and the gate spacers 38 are formed. In FIG. 4A, each one of the dummy gate structures 34 and the gate spacers 38 extends along the second direction and across the first and second fin structures 24a, 24b. Each one of the dummy gate structures 34 is sandwiched between the gate spacers 38, and the gate spacers 38 is disposed on opposite sidewalls of each dummy gate structure 34. In FIG. 4B, the dummy gate structures 34 are formed on top surfaces and sidewalls of the dummy gate dielectrics 32.

In some embodiments, the dummy gate structures 34 are formed then the gate spacers 38 are formed on the dummy gate structures 34. For example, the dummy gate structures 34 are formed by using polysilicon or amorphous silicon, or the like. In some embodiments, the dummy gate structures 34 are formed by a chemical vapor deposition (CVD). For example, the gate spacers 38 are formed of a dielectric material such as silicon nitride (SiN), silicon oxide, silicon carbo-nitride (SiCN), silicon oxynitride (SiON), silicon oxy-carbo-nitride (SiOCN), or the like, and may have a single-layer structure or a multilayer structure including a plurality of dielectric layers. In some embodiments, the formation process of gate spacers 38 may include depositing one or more dielectric layers, and then performing one or more anisotropic etching processes on the dielectric layer(s). The remaining portions of the dielectric layer(s) are the gate spacers 38.

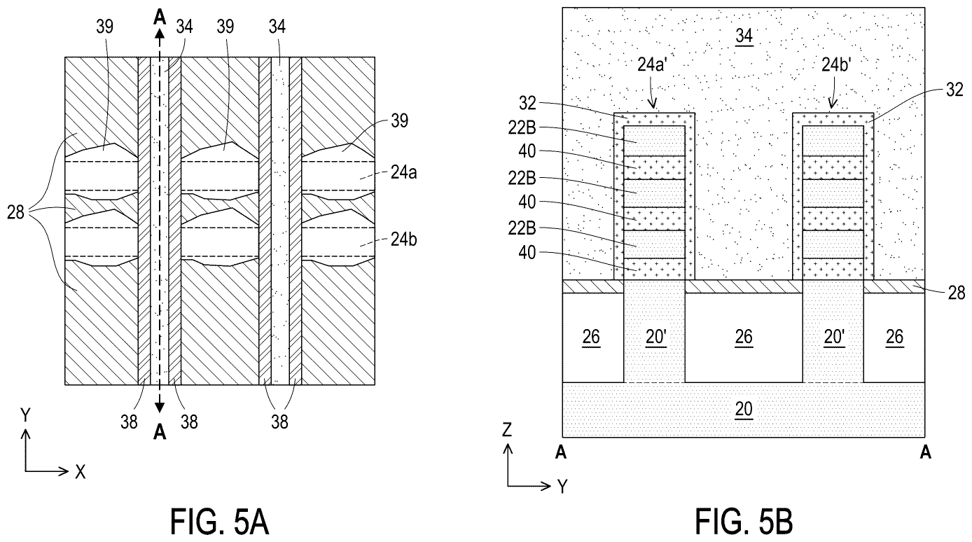

Referring to FIG. 5A and FIG. 5B, FIG. 5A is a schematic t view of the structure, and FIG. 5B illustrates the schematic cross-sectional view along the cross-sectional line A-A in FIG. 5A. Referring to FIG. 5A, after the gate spacers 38 are formed, recesses (not shown) for forming source/drain regions 39 are formed. In some embodiments, the formation of the recesses includes performing an etching process to remove the portions of the first and second fin structures 24a, 24b that are not overlapped with and not directly underlying dummy gate dielectrics 32, the dummy gate structures 34 and gate spacers 38. For example, a dry etch process is performed by using C₂F₆, CF₄, SO₂, the mixture of HBr, Cl₂, and O₂, the mixture of HBr, Cl₂, O₂, and CH₂F₂, or the like. In some embodiments, the etching process includes anisotropic etching process.

Referring to FIG. 5B, after the recesses (not shown) of FIG. 5A are formed, the remained first semiconductor layers 22A (referred to as sacrificial layers) are removed. The recesses are further formed between the second semiconductor layers 22B of the first and second fin structures 24a, 24b, and between the bottommost second semiconductor layers 22B and the protruding fins 20′. In some embodiments, the first semiconductor layers 22A are removed by performing an anisotropic etching process such as a dry etching process using gas etchants which are selective to the materials of the first semiconductor layers 22A, while the second semiconductor layers 22B, the substrate 20, the hard mask layer 28 remain relatively un-etched as compared to the first semiconductor layers 22A. For example, the first semiconductor layers 22A include SiGe, and the second semiconductor layers 22B include Si, etchants or reactants such as fluorine (F₂) (gas), hydrogen fluoride (HF) (gas) and a combination thereof are used to remove the first semiconductor layers 22A. In some embodiments, the anisotropic etching process is performed under a temperature from about 0 °C to about 100 °C.

Referring to FIG. 5B, after the first semiconductor layers 22A are removed, dummy oxide layers 40 fills the recesses between the second semiconductor layers 22B and between the bottommost second semiconductor layers 22B and the protruding fins 20′ to form first and second fin structures 24a+, 24b+. The first and second fin structures 24a+, 24b′ each includes the dummy oxide layers 40 and the second semiconductor layers 22B alternative stacked to each other in the third direction (e.g. Z-direction). Each dummy oxide layers 40 is joined to the dummy gate dielectrics 32. The dummy oxide layers 40 and the second semiconductor layers 22B are in contact with the dummy gate dielectrics 32.

In some embodiments, a material of the dummy oxide layers includes such as an oxide material such as a silicon oxide, silicon oxynitride (SiON), a combination thereof, or the like. In some embodiments, the dummy oxide layers 40 are formed by a plasma-enhanced atomic layer deposition (PEALD), FCVD, a combination thereof, or the like. In some embodiments, the material of the dummy gate dielectrics 32 and the material of the dummy oxide layers 40 may be the same material.

Referring to FIG. 5A, after the dummy oxide layers 40 are formed, the source/drain regions 39 are formed in the recesses (not shown) between the first and second fin structures 24a′, 24b′ and on the protruding fins 20′. The source/drain regions 39 are in contact with the second semiconductor layers 22B, and the dummy oxide layers 40 shown in FIG. 5B. For example, the source/drain regions 39 include semiconductor material. In some embodiments, the formation of the source/drain regions 39 includes performing an epitaxy process. For example, the source/drain regions 39 are epitaxially grown from the second semiconductor layers 22B or from protruding fins 20′ of the substrate 20. In some embodiments, transistor is a p-type transistor or an n-type transistor, and a p-type or an n-type impurity is in-situ doped with the proceeding of the epitaxy process. For example, when the transistor is a p-type transistor, silicon germanium boron (SiGeB), silicon boron (SiB), or the like is grown. Conversely, when the transistor is an n-type transistor, silicon phosphorous (SiP), silicon carbon phosphorous (SiCP), or the like is grown. In alternative embodiments, after the epitaxy process, the source/drain regions 39 are further implanted with a p-type or an n-type impurity to form source and drain regions.

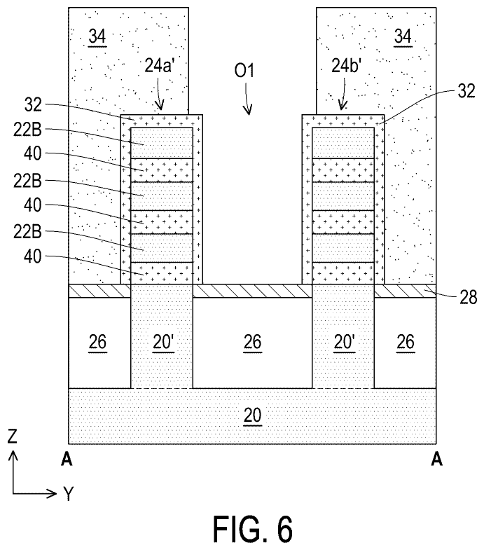

Referring FIG. 6, FIG. 6 illustrates the schematic cross-sectional view. In some embodiments, a cut-opening forming process is performed to form openings O1 (e. g gate cut-openings) (only one opening is shown in FIG. 6) in the dummy gate structures 34 through photolithography and etching process. Through such process, portions of the dummy gate structures 34 are removed to form the openings O1 at predetermined locations in the dummy gate structures 34 and between the gate spacers 38. The opening O1 is formed between the dummy gate dielectrics 32 of the first and second fin structures 24a′, 24b′ and reveals portions of the dummy gate structures 34, the dummy gate dielectrics 32 and the hard mask layer 28. In some embodiments, the dummy gate dielectrics 32 formed on sidewalls of the first and second fin structures 24a′, 24b′ are revealed by the opening O1. In some embodiments, a width of a top of the opening O1 may be substantially similar to or slightly greater than a width of a bottom of the opening O1 between the first and second fin structures 24a′, 24b′ to ensure that the dummy gate dielectrics 32 formed on the sidewalls of the first and second fin structures 24a′, 24b′ are revealed by the opening O1. Based on etching selectivity, the etching of the openings O1 terminates at the gate spacers 38, so that both sidewalls of the opening O1 formed within the dummy gate structures 34 abut the gate spacers 38 from a top view (not shown).

In some embodiments, the cut-opening forming process includes an etching process such as a wet etching process, or any suitable process. In some embodiments, a photoresist (not shown) is formed over the dummy gate structures 34. The photoresist may then be patterned by using photolithography techniques to generate an opening in the photoresist. The patterned photoresist may then be used as a mask for patterning the dummy gate structures 34. After performing the cut-opening forming process, any residual photoresist is removed by an ash process or by dissolution with a solvent.

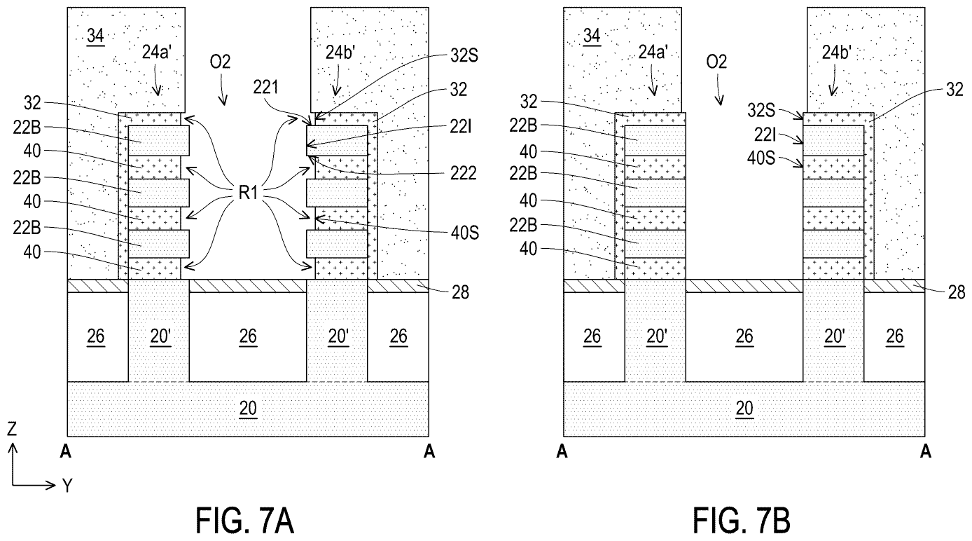

Referring FIG. 7A and FIG. 7B, FIG. 7A is a schematic top view of the structure, and FIG. 7B illustrates the schematic cross-sectional view along the cross-sectional line A-A in FIG. 7A. In some embodiments, a lateral etching process is performed to the dummy gate dielectrics 32 revealed by the openings O1, so that the dummy gate dielectrics 32 that is formed on sidewalls of the first and second fin structures 24a′, 24b′ and revealed by the openings O1 are removed. In some embodiments, as shown in FIG. 7A, by tuning the etching selectivity, portions of the dummy gate dielectrics 32 and portions of the dummy oxide layers 40 that are revealed by the openings O1 are selectively removed. That is, following the removal of the revealed dummy gate dielectrics 32, the dummy oxide layers 40 revealed are also removed and laterally recessed. In some embodiments, the lateral etching process has high etching selectivity toward the oxide materials over semiconductor materials (i.e. higher etching rates for the oxide materials, and lower or minimal etching rates for the semiconductor materials). After performing the lateral etching process, the openings O1 become the openings O2, and inner sidewalls 22I (e. g facing sidewalls) of the second semiconductor layers 22B, sidewalls 32S (e. g facing sidewalls) of the dummy gate dielectrics 32, and sidewalls 40S (e. g facing sidewalls) of the dummy oxide layers 40 are revealed by the opening O2.

In FIG. 7A, the dummy gate dielectrics 32 and the dummy oxide layers 40 are laterally recessed to form lateral recesses R1 in the opening O2. In some embodiments, the inner sidewalls 22I of the second semiconductor layers 22B are misaligned with the sidewalls 32S of the remained dummy gate dielectrics 32 and the sidewalls 40S of the remained dummy oxide layers 40. In some embodiments, the lateral recesses R1 reveal the inner sidewalls 22I of the second semiconductor layers 22B. In some embodiments, the lateral recesses R1 reveal portions of top surfaces 221 and portions of bottom surfaces 222 of the second semiconductor layers 22B2. In some embodiments, the second semiconductor layers 22B laterally protrude from the sidewalls 32S of the dummy gate dielectrics 32 and the sidewalls 40S of the dummy oxide layers 40.

In some embodiments, the lateral etching process includes an etching process using an etchant that is more selective to the material of the dummy gate dielectrics 32 and the dummy oxide layers 40 than the material of the second semiconductor layers 22B and the protruding fins 20′ and the dummy gate structures 34. In some embodiments, the etching process is performed by using one or more etchants such as hydrogen fluoride (HF), ammonia (NH₃), hydrofluoric acid (DHF), a combination thereof, or the like. In some embodiments, the etching process is performed under a temperature from about 0 °C to about 150 °C and at a pressure from 0.1 Torr to about 100 Torr.

In some embodiments, as shown in FIG. 7B, by tuning the etching selectivity, portions of the dummy gate dielectrics 32 that are revealed by the openings O1 are selectively removed to become the openings O2. Different from FIG. 7A, following the removal of the revealed dummy gate dielectrics 32, the revealed dummy oxide layers 40 substantially remain intact and non-removed. After forming the openings O2, and the inner sidewalls 22I (e. g facing sidewalls) of the second semiconductor layers 22B, the sidewalls 32S (e. g facing sidewalls) of the dummy gate dielectrics 32, and the sidewalls 40S (e. g facing sidewalls) of the dummy oxide layers 40 are revealed by the opening O2.

In FIG. 7B, the inner sidewalls 22I of the second semiconductor layers 22B are aligned with the sidewalls 40S of the dummy oxide layers 40. In some embodiments, the sidewalls 32S of the dummy gate dielectrics 32 are aligned with the inner sidewalls 22I of the second semiconductor layer 22 and the sidewalls 40S of the dummy oxide layers 40. In some embodiments, the dummy gate dielectrics 32 are laterally recessed to form lateral recesses, the sidewalls 32S of the dummy gate dielectrics 32 are misaligned with the inner sidewalls 22I of the second semiconductor layers 22B and the sidewalls 40S of the dummy oxide layers 40.

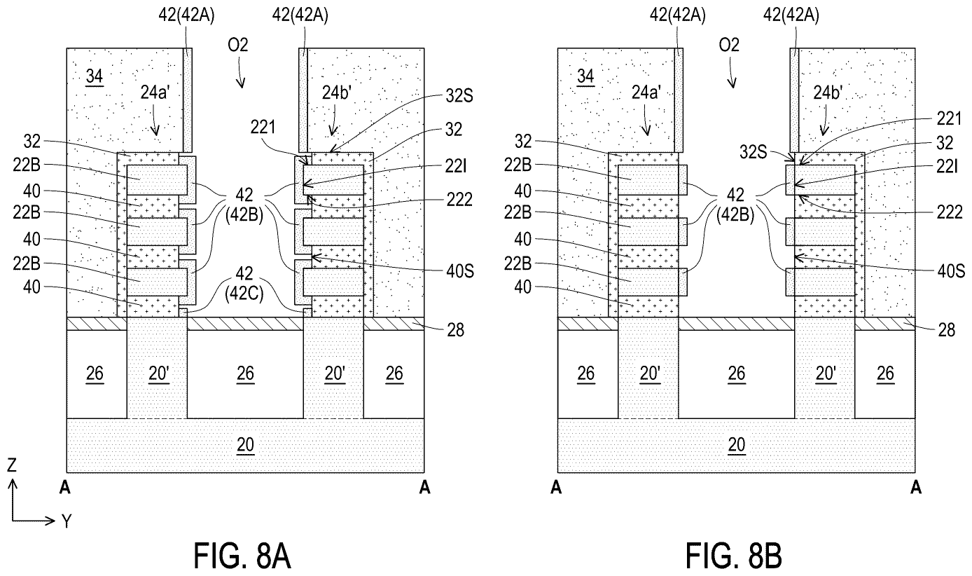

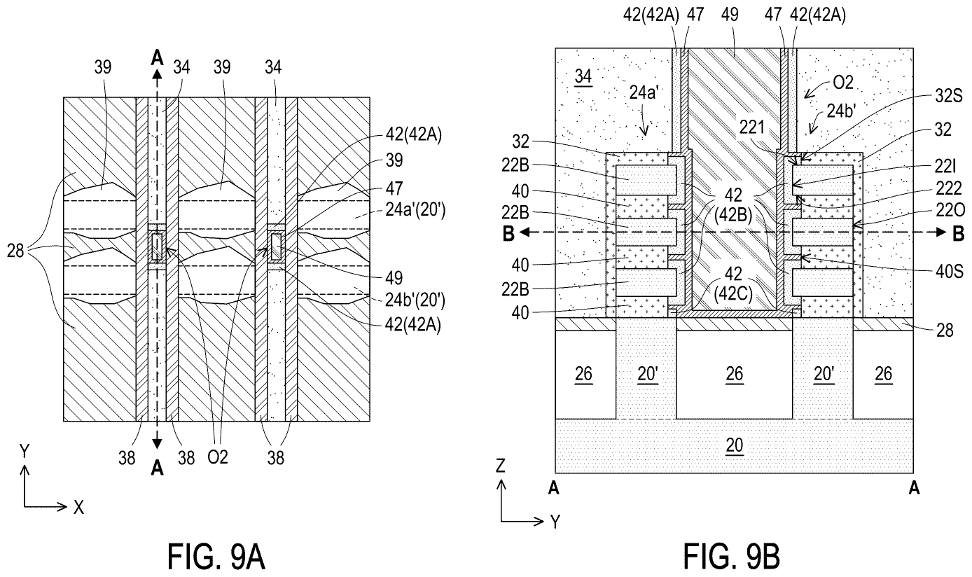

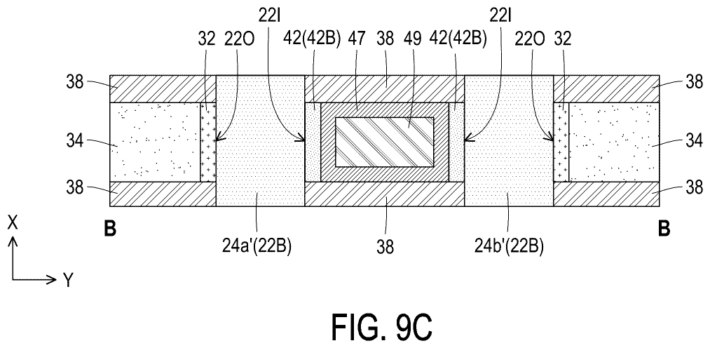

Referring FIG. 8A and FIG. 8B, FIG. 8A is a schematic top view of the structure, and FIG. 8B illustrates the schematic cross-sectional view along the cross-sectional line A-A in FIG. 8A. In some embodiments, protection layers 42 are formed within the openings O2. By way of selective growth mechanism, the protection layers 42 are selectively formed, and are formed selectively only on the surface(s) of the semiconductor material (such as silicon). In some embodiments, the protection layers 42 are selectively formed on the revealed second semiconductor layers 22B of the first and second fin structures 24a′, 24b′, on the revealed dummy gate structures 34, and optionally on the revealed protruding fins 20′, within the openings O2. Through material choices, the protection layers 42 are not formed on the gate spacers 38 but are selectively formed on the revealed sidewalls of the first and second fin structures 24a′, 24b′, and on the revealed sidewalls of the dummy gate structures 34 within the openings O2 that are located between a pair of the gate spacers as shown in FIG. 9A and FIG. 9C. In some embodiments, the protection layers 42 are selectively grown from the revealed second semiconductor layers 22B of the first and second fin structures 24a′, 24b′, on the revealed dummy gate structures 34, and optionally on the revealed protruding fins 20′, within the openings O2.

In FIG. 8A, the protection layers 42 includes first portions 42A on the revealed dummy gate structures 34, second portions 42B on the revealed second semiconductor layers 22B of the first and second fin structures 24a′, 24b′, and third portions 42C on the revealed protruding fins 20′. In some embodiments, the first portions 42A are in contact with the dummy gate structures 34. In some embodiments, due to the material differences in the underlying underlayers (such as the revealed dummy gate structures 34, the revealed second semiconductor layers 22B of the first and second fin structures 24a′, 24b′, and the revealed protruding fins 20′), the first portions 42A include amorphous silicon germanium, while the second portions 42B and the third portions 42C include crystalline silicon germanium.

In FIG. 8A, in some embodiments, the second portions 42B cover the whole revealed surfaces such as the inner sidewalls 22I, portions of the top surfaces 221 and the bottom surfaces 222 of the second semiconductor layers 22B. In some embodiments, the second portions 42B extend into the lateral recesses R1, shown in FIG. 7A. In some embodiments, the second portions 42B are in contact with the sidewalls 32S of the dummy gate dielectrics 32, the inner sidewalls 22I of the second semiconductor layers 22B and the sidewalls 40S of the dummy oxide layers 40. In some embodiments, the third portions 42C are in contact with the sidewalls 40S of the dummy oxide layers 40 and the protruding fins 20′. For example, the second portions 42B may be “C” shapes wrap around the second semiconductor layers 22B, viewing from a cross-sectional view in a plane of the second direction and the third direction.

In FIG. 8B, the protection layers 42 include first portions 42A on the revealed dummy gate structures 34, and second portions 42B on the revealed second semiconductor layers 22B of the first and second fin structures 24a′, 24b′. In some embodiments, the first portions 42A are in contact with the dummy gate structures 34. In some embodiments, the second portions 42B cover the inner sidewalls 22I of the second semiconductor layers 22B. In some embodiments, the second portions 42B are in contact with the inner sidewalls 22I of the second semiconductor layers 22B.

In some embodiments, a material of the protection layers 42 include such as a material such as a silicon-germanium (SiGe), or the like. In some embodiments, the protection layers 42 are formed through selective epitaxy growth mechanism by performing one or more deposition processes such as chemical vapor deposition (CVD) or atomic layer deposition (ALD) using one or more precursors such as silane (SiH₄), chlorosilane (SiH₃Cl), dichlorosilane (SiH₂Cl₂), trichlorosilane (SiHCl₃), silicon chloride (SiCl₄), germane (GeH₄), germanium tetrachloride (GeCl₄), or a combination thereof, or optionally in combination with HCl. In some embodiments, the deposition process is performed under a temperature from about 400 °C to about 700 °C and at a pressure from 1 torr to about 760 torr. After the deposition process is performed, the protection layers 42 grow from the revealed dummy gate dielectrics 32, the second semiconductor layers 22B, and the protruding fins 20′. In some embodiments, the deposition process of the protection layers 42 may be performed along with an etching process at the same time (e.g. a co-localized etching process). In some embodiments, the addition of hydrochloric acid (HCl) may enhance the growth selectivity and help to selectively remove the undesired deposition growing from the dummy gate dielectrics 32, the dummy oxide layers 40, and the hard mask layer 28.

Referring to FIG. 9A and FIG. 9B, FIG. 9A is a schematic top view of the structure, FIG. 9B illustrates the schematic cross-sectional view along the cross-sectional line A-A in FIG. 9A., FIG. 9C illustrates the schematic cross-sectional view along the cross-sectional line B-B in FIG. 9B. Referring to FIG. 9A and FIG. 9B, dielectric liner layers 47 and dielectric blocks 49 are formed within the openings O2. Each dielectric liner layer 47 is conformally formed on and in contact with the protection layers 42 and the sidewalls of the gate spacers 38, shown in FIG. 9A. Each dielectric liner layer 47 is conformally formed on and in contact with the dummy gate structures 34, the dummy gate dielectrics 32, the protection layers 42 and the STI regions 26, shown in FIG. 9B.

After the dielectric liner layers 47 are formed, a dielectric material fills within the opening O2 to form the dielectric blocks 49. The dielectric blocks 49 is enclosed by the dielectric liner layer 47. Each dielectric block is separated from the gate spaces 38, the dummy gate structures 34, the dummy gate dielectrics 32, the protection layers 42 and the STI regions 26 by the corresponding dielectric liner layer 47.

Referring to FIG. 9C, FIG. 9C illustrates the cross-sectional view of line C-C in FIG. 9B. The dummy gate dielectrics 32 are sandwiched between the gate spaces 38, and between the dummy gate structures 34 and the second portion 42B of the protection layers 42. The dummy gate dielectrics 32 are disposed on outer sidewalls 22O of the second semiconductor layers 22B of the first and second fin structure 24a′, 24b. the outer sidewalls 22O are opposite to the inner sidewalls 22I of the second semiconductor layers 22B.

The second portion 42B of the protection layers 42 are sandwiched between the second semiconductor layers 22B and the dielectric liner layer 47. The second portion 42B are disposed on the inner sidewalls 22I of the second semiconductor layers 22B of the first and second fin structure 24a′, 24b. The dielectric liner layers 47 are enclosed by the gate spacer 38 and the protection layers 42. The dielectric block 49 is enclosed by the dielectric liner layer 47.

In some embodiments, a material of the dielectric liner layers 47 include such as an oxide material such as a silicon oxide, SiON, or the like. In some embodiments, the protection layers 42 are formed by a deposition process such as thermal ALD and plasma assisted ALD. In some embodiments, a material of the dielectric blocks 49 includes such as a nitride material such as a SiN, SiCN, SiOCN., or the like. In some embodiments, the dielectric blocks 49 are formed by a deposition process such as thermal ALD and plasma assisted ALD.

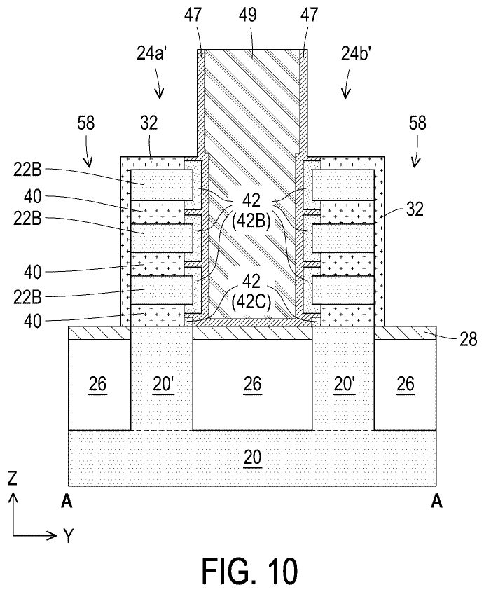

Referring to FIG. 10, FIG. 10 illustrates the schematic cross-sectional view. In some embodiments, the dummy gate structures 34 are removed to form recesses 58 to reveal the dummy gate dielectrics 32 and the dielectric liner layers 47. In some embodiments, a removal process is performed by using plasma dry etching and/or wet etching. For example, when the dummy gate structures 34 are polysilicon, a wet etchant such as a tetramethylammonium hydroxide (TMAH) solution may be used to selectively remove the dummy gate structures 34 without removing the dummy gate dielectrics 32, the hard mask layer 28, the dielectric liner layers 47, and the dielectric blocks 49.

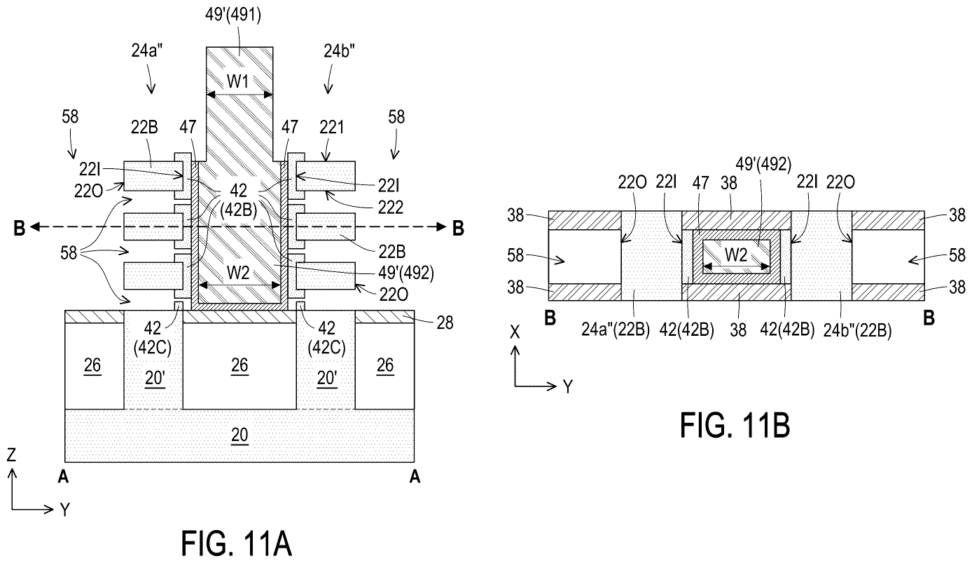

Referring to FIG. 11A and FIG. 11B, FIG. 11A illustrates the schematic cross-sectional view, and FIG. 11B illustrates the schematic cross-sectional view along the cross-sectional line B-B in FIG. 11A. Referring to FIG. 11A and FIG. 11B, the dummy gate dielectrics 32, the dummy oxide layers 40, portions of the dielectric liner layer 47 and portions of the dielectric blocks 49 are removed to further form the recesses 58 between the second semiconductor layers 22B. After the removal process, the first and second fin structure 24a″, 24b″ are also formed. The first and second fin structure 24a″, 24b″ each includes the second semiconductor layers 22B vertically stacked over the protruding fin 20′ and spaced apart from one another by the recesses 58. The recesses 58 reveal the whole outer sidewalls 22O, the portions of the top surfaces 221 and the portions of the bottom surfaces 222 of the second semiconductor layers 22B, while the protection layers 42 are remained and cover the inner sidewalls 22I, the remained portions of the top surfaces 221 and the remained portions of the bottom surfaces 222 of the second semiconductor layers 22B.

In some embodiments, the “C” shapes of the second portions 42B of the protection layers 42 protects the inner sidewalls 22I, the remained portions of the top surfaces 221 and the bottom surfaces 222, thereby the protection layers 42 prevent the corners of the inner sidewalls 22I of the second semiconductor layers 22B from forming the rounded corners in the removal process of the dummy gate dielectrics 32 and the dummy oxide layers 40.

In some embodiments, the recesses 58 reveal the protruding fins 20′ and the protection layer 42 is remained on portions of the protruding fins 20′. In some embodiments, the recesses 58 reveal the protection layer 42 and the dielectric liner layers 47. After removal process, the trimmed dielectric blocks 49′ are also formed. The trimmed dielectric blocks 49′ include an upper portion 491, and a lower portion 492 extending from the upper portion 491, The upper portion extends from the lower portion and is disposed above the first and second fin structures. The lower portion 492 is enclosed by the dielectric liner layers 47, and disposed between the first and second fin structures 24a″, 24b″. The recesses 58 reveal the upper portion 491 of the trimmed dielectric blocks 49′. In some embodiments, the upper portion 491 has a lateral dimension W1 in the second direction smaller than a lateral dimension W2 of the lower portion 492 in the second direction. In FIG. 11B, the recesses 58 reveal portions of the gate spacers 38.

In some embodiments, a removal process is performed by using a selective etching process. In some embodiments, the dummy gate dielectrics 32, the dummy oxide layers 40, the dielectric liner layer 47 and the dielectric blocks 49 are selectively etched using an etchant having an etching selectivity that causes the dummy gate dielectrics 32, the dummy oxide layers 40, the portions of the dielectric liner layer 47 and the portions of the dielectric blocks 49 to be etched much faster than the protection layers 42. The high etching selectivity allows for the dummy gate dielectrics 32, the dummy oxide layers 40, the portions of the dielectric liner layer 47 and the portions of the dielectric blocks 49 to be removed without removing the protection layers 42. For example, in some embodiments, the dummy gate dielectrics 32, the dummy oxide layers 40, the dielectric liner layer 47 may include the oxide material, the dielectric block 49 may include the nitride material, and the protection layers 42 may include a semiconductor material such as silicon germanium. In such embodiments, the etching selectivity of the oxide material and the nitride material to the semiconductor material is high etching selectivity during the etching process.

For example, the etching process is performed by using gas etchants which are selective to the materials of the dummy gate dielectrics 32, the dummy oxide layers 40, the dielectric liner layer 47 and the dielectric blocks 49, while the protection layers 42 remain relatively un-etched as compared to the dummy gate dielectrics 32, the dummy oxide layers 40, the dielectric liner layer 47 and the dielectric blocks 49. In some embodiments, the gas etchants include gas such as HF, NH₃, and a combination thereof, or the like.

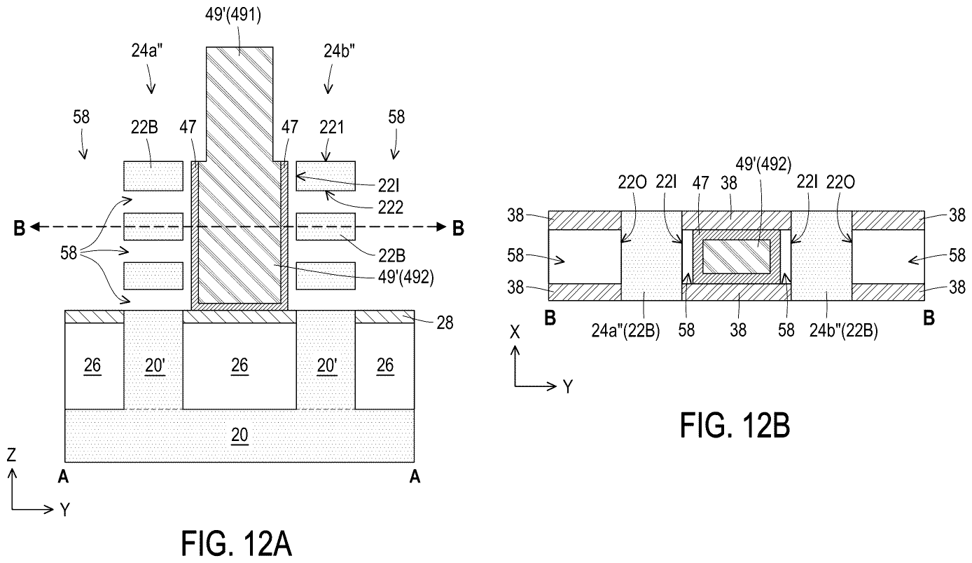

Referring to FIG. 12A and FIG. 12B, FIG. 12A illustrates the schematic cross-sectional view, and FIG. 12B illustrates the schematic cross-sectional view along the cross-sectional line B-B in FIG. 12A. Referring to FIG. 12A and FIG. 12B, the protection layers 42 are removed to further form the recesses 58 between the second semiconductor layers 22B of the first and second fin structure 24a″, 24b″ and the dielectric liner layers 47. The recesses 58 reveal the dielectric liner layers 47 and the inner sidewalls 22I of the second semiconductor layers 22B. In some embodiments, a removal process is performed by using a selective dry etching process or a selective wet etching process. In some embodiments, the protection layers 42 are selectively etched using an etchant having an etching selectivity that causes the protection layers 42 to be etched much faster than the dielectric liner layer 47 and the dielectric block 49. The high etching selectivity allows for the protection layers 42 to be removed without removing the dielectric liner layer 47 and the dielectric block 49. For example, in some embodiments, the protection layers 42 may include a semiconductor material such as silicon germanium and the dielectric liner layer 47 may include the oxide material and the dielectric block 49 may include the nitride material. In such embodiments, the etching selectivity of the semiconductor material to the oxide material and the nitride material is high etching selectivity during the etching process. For example, the etching process is performed by using at least an etchant selected from fluorine and ammonia such as F₂ (gas), HF (gas), and NH₃ combined with H₂ plasma.

In some embodiments, a refresh process is performed on the inner sidewalls 22I, the top surfaces 221 and the bottom surfaces 222 of the second semiconductor layers 22B that is in contact with the protection layer 42 in previous stage of the process. In some embodiments, the refresh process is performed by using gas etchants such as F₂, HF, HBr and a combination thereof under a temperature from about 0 °C to about 100 °C. The refresh process may etch out the diffusion or the contamination such as Ge to improve the electrical performance of the subsequently formed semiconductor device.

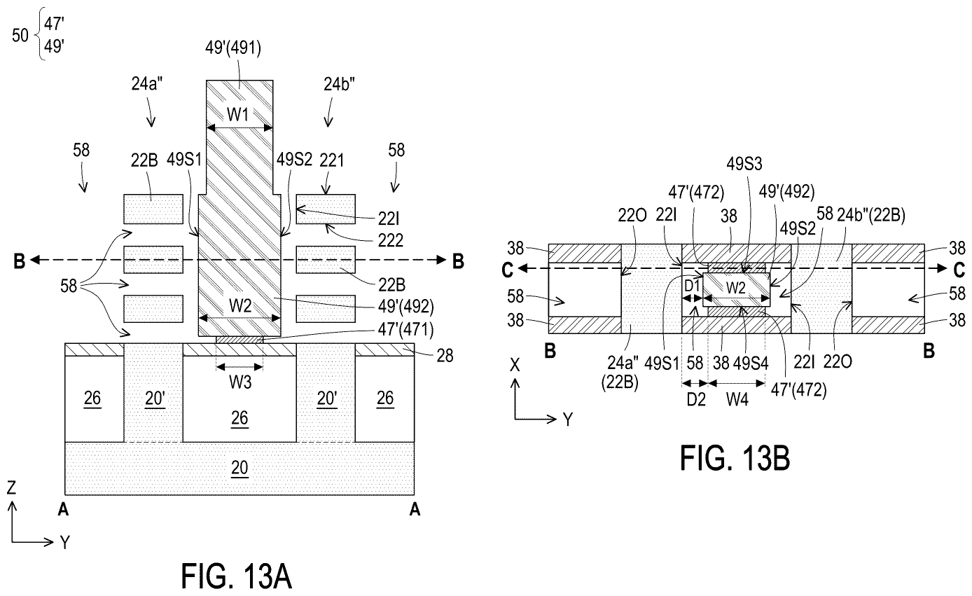

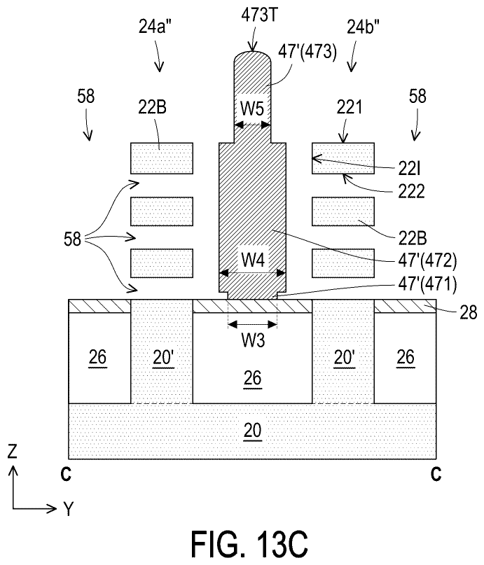

Referring to FIG. 13A and FIG. 13B, FIG. 13A illustrates the schematic cross-sectional view, FIG. 13B illustrates the schematic cross-sectional view along the cross-sectional line B-B in FIG. 13A, and FIG. 13C illustrates the schematic cross-sectional view along the cross-sectional line C-C in FIG. 13B. Referring to FIG. 13A and FIG. 13B, the portions of the dielectric liner layers 47 are removed to further form the recesses 58 that reveal sidewalls 49S1, 49S2 and partially reveal a bottom surface 49B of the trimmed dielectric blocks 49′, as shown in FIG. 13A. In some embodiments, the recesses 58 partially reveal sidewalls 49S3, 49S4 of the trimmed dielectric blocks 49′, as shown in FIG. 13B. The sidewalls 49S1 and 49S2 are opposite to each other in the second direction. The sidewalls 49S3 and 49S4 are opposite to each other in the first direction.

The dielectric liner layers 47 formed on sidewalls 49S1, 49S2 of the trimmed dielectric blocks 49′ and sandwiched between the inner sidewalls 22I of the second semiconductor layers 22B and the lower portion 492 of the trimmed dielectric blocks 49′ are removed. The dielectric liner layers 47 formed on sidewalls 49S3, 49S4 and the bottom surface 49B of the trimmed dielectric blocks 49′ are partially removed. The recesses 58 are formed between the sidewall 49S1 of the trimmed dielectric blocks 49′ and the inner sidewall 22I of the first structure 24a″, and between the sidewall 49S2 of the trimmed dielectric blocks 49′ and the inner sidewall 22I of the second fin structure 24b″.

In some embodiments, the removal process includes a dry etching process or a wet etching process. In some embodiments, the etching process is performed by using the etchant such as hydrofluoric acid (DHF). In some embodiments, the etching process is performed by using the etchant such as hydrogen fluoride (HF), ammonia (NH₃), a combination thereof, or the like.

Referring to FIG. 13C, dielectric liner layers 47′ are formed, after the removal process. FIG. 13C illustrates the cross-sectional view of line C-C in FIG. 13B. FIG. 13C shows the dielectric liner layers 47′ formed on the sidewall 49S3 of the trimmed dielectric blocks 49'. The dielectric liner layers 47′ include a lower portion 471 formed on the hard mask layer, a middle portion 472 extending from the lower portion 471 and disposed beside the second semiconductor layers 22B, and an upper portion 473 extending and protruding from the middle portion 472. A separation structure 50 is consisted of the dielectric liner layer 47′ and the trimmed dielectric blocks 49', and the separation structure 50 disposed between the first and second fin structures 24a″, 24b″.

Referring to FIG. 13A through FIG. 13C, each dielectric liner layer 47′ extends from the sidewall 49S3, along the bottom surface 49B to sidewall 49S4 of the trimmed dielectric block 49′. In some embodiments, the upper portion 473 includes a top surface 473T having a convex shape. In some embodiments, the middle portion 472 has a lateral dimension W4 in the second direction greater than a lateral dimension W3 of the lower portion 471 and a lateral dimension W5 of the upper portion 473 in the second direction. The middle portions 472 of the dielectric liner layers 47′ disposed on sidewalls 49S3, 49S4 of the trimmed dielectric block 49′ are each laterally recessed. In some embodiments, a distance D1 between the inner sidewall 22I and the sidewall 49S1 of the trimmed dielectric block 49′ is less than a distance D2 between the inner sidewall 22I and the middle portions 472 of the dielectric liner layers 47′. In some embodiments, a ratio of the distance D1 to the distance D2 ranges from about 1:1.1 to about 1:1.7.

In some embodiments, the lateral dimension W2 of the lower portion 492 of the trimmed dielectric blocks 49′ is greater than the lateral dimension W4 of the middle portion 472 of the dielectric liner layers 47'. In some embodiments, a ratio of the lateral dimension W4 of the trimmed dielectric blocks 49′ to the lateral dimension W2 of the dielectric liner layers 47′ ranges from about 1:0.75 to about 1:0.98.

In some embodiments, the lateral dimension W3 of the upper portion 473 of the dielectric liner layers 47′ is smaller than lateral dimension W2 of the lower portion 492 of the trimmed dielectric blocks 49′.

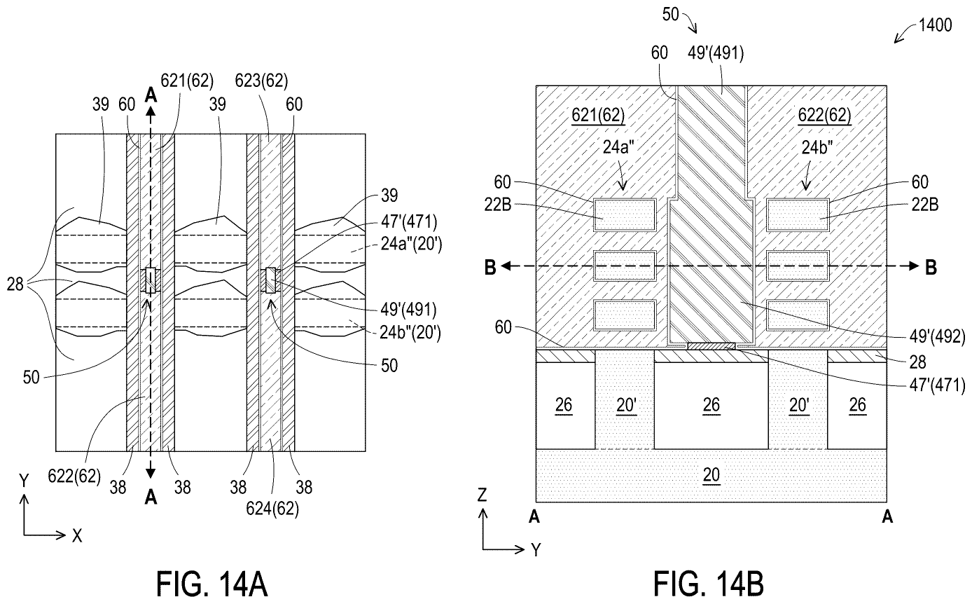

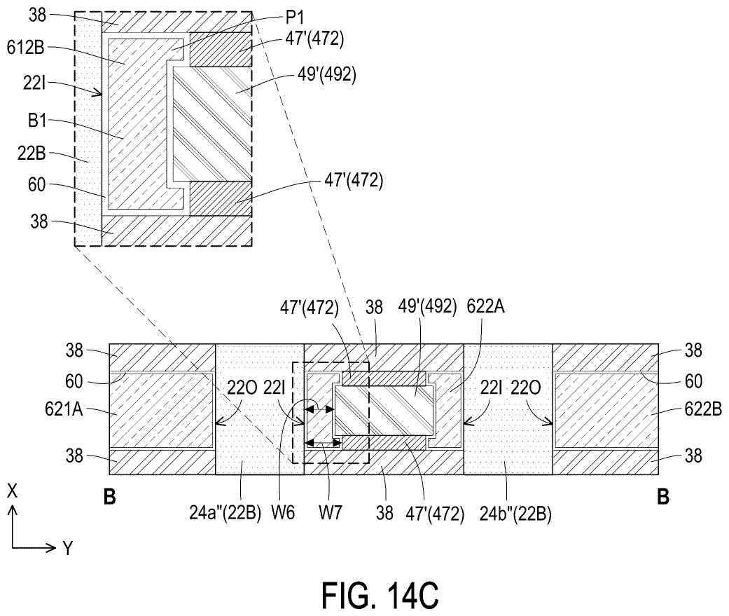

Referring to FIG. 14A and FIG. 14B, FIG. 14A is a schematic top view of the structure, FIG. 14B illustrates the schematic cross-sectional view along the cross-sectional line A-A in FIG. 14A, and FIG. 14C illustrates the schematic cross-sectional view along the cross-sectional line B-B in FIG. 14B. Referring to FIG. 14A through FIG. 14C, high-k dielectric layers 60 and gate electrodes are formed. The high-k dielectric layer 60 is conformally formed to wrap around and in contact with the second semiconductor layers 22B, and cover and in contact with the protruding fins 20′. The high-k dielectric layer 60 covers and in contact with the trimmed dielectric blocks 49′, the dielectric liner layers 47′ and the hard mask layer 28. In some embodiments, an interfacial dielectric layer (not shown) is conformally formed on the second semiconductor layers 22B and the protruding fins 20′ before the high-k dielectric layer 60 is formed.

The high-k dielectric layer 60 includes one or more dielectric layers. For example, the high-k dielectric layer 60 includes hafnium oxide (HfOx), aluminum oxide (AlOx), zirconium oxide (ZrOx), lanthanum oxide (LaOx), zinc oxide (ZnOx), other suitable high-k dielectric materials, and/or combinations thereof. In some embodiments, the high-k dielectric layer 60 is formed by CVD, ALD, or any suitable method.

The gate electrode 62 is formed on high-k dielectric layer 60 covers high-k dielectric layer 60, wraps around the second semiconductor layers 22B, and fill the remaining portions of recesses 58, as shown in Referring to FIG. 13A through FIG. 13C. The gate electrode 62 includes a first gate electrode 621 extending along the second direction and across the first fin structure 24a″, and a second gate electrode 622 extending along the second direction and across the second fin structure 24b″. The separation structure 50 separates the first electrode 621 from the second gate electrode 622. In some embodiments, the additional gate electrode 62 that is adjacent to the gate electrode 62 includes a first gate electrode 623 extending along the second direction and across the first fin structure 24a″, and a second gate electrode 624 extending along the second direction and across the second fin structure 24b″. The separation structure 50 separates the first electrode 623 from the second gate electrode 624.

The gate electrode 62 includes a metal-containing material such as titanium nitride (TiN), tantalum nitride (TaN), titanium aluminide (TiAl), titanium aluminum carbide (TiAlC), tantalum aluminum carbide (TaAlC), tungsten carbonitride (WCN), molybdenum (Mo), any suitable material, combinations thereof, and/or multilayers thereof. For example, although in FIG. 14A through FIG. 14C, a single layer is illustrated to represent the gate electrode 62, the gate electrode 62 may include any number of the gate electrode layers. In some embodiments, the gate electrode 62 is formed by a deposition process such as CVD, ALD, or any suitable method. After the deposition process is performed, a planarization process such as a CMP process or a mechanical grinding process is performed to remove the excess material of the gate electrode 62 until reaching a desired thickness. After the CMP process, a forksheet structure 1400 is formed, as shown in FIG. 14B.

Referring to FIG. 14C, the first electrode 621 includes a first portion 621A disposed on the outer sidewalls 22O and a second portion 621B disposed on the inner sidewalls 22I. The second electrode 622 includes a first portion 622B disposed on the outer sidewalls 22O and a second portion 622A disposed on the inner sidewalls 22I. The first portion 621B of the first electrode 621 and the second portion 622A of the second electrode 622 each includes a base portion B1 sandwiched between the first fin structure 24a″ and the trimmed dielectric block 49′, and protrusions P1 protruding from the base portion B1 to the dielectric liner layers 47′. In some embodiment, a lateral dimension W6 in the second direction is a sum of a lateral dimension of the base portion B1 in the second direction and a lateral dimension of the high-k dielectric layer 60 in the second direction. In some embodiment, a lateral dimension W7 in the second direction is a sum of a lateral dimension of the protrusion P1 in the second direction and a lateral dimension of the high-k dielectric layer 60 in the second direction. In some embodiment, a ratio of the lateral dimension W6 to the lateral dimension W7 ranges from about 1:1.1 to about 1:1.7.

Each base portion B1 is in contact with the sidewalls 49S1 or 49S2 of the trimmed dielectric block 49′ and the second semiconductor layer 22B. The protrusions P1 are each sandwiched between the trimmed dielectric block 49′ and the gate spacer 38. The protrusions P1 are in contact with the middle portions 472 of the dielectric liner layers 47′ and the sidewalls 49S3, 49S4 of the trimmed dielectric block 49′.

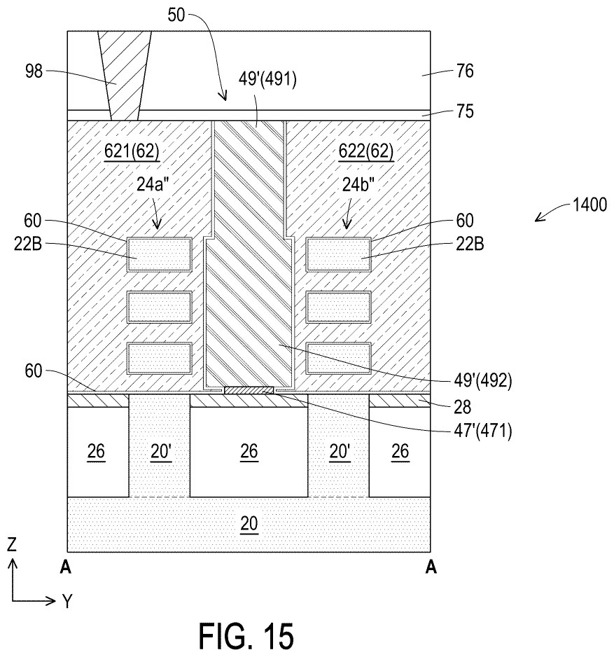

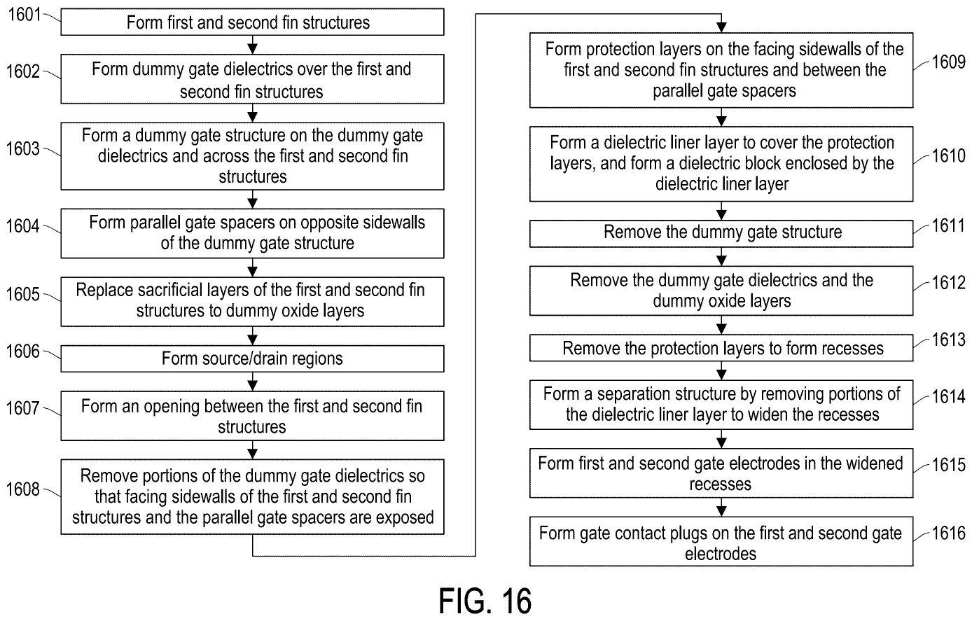

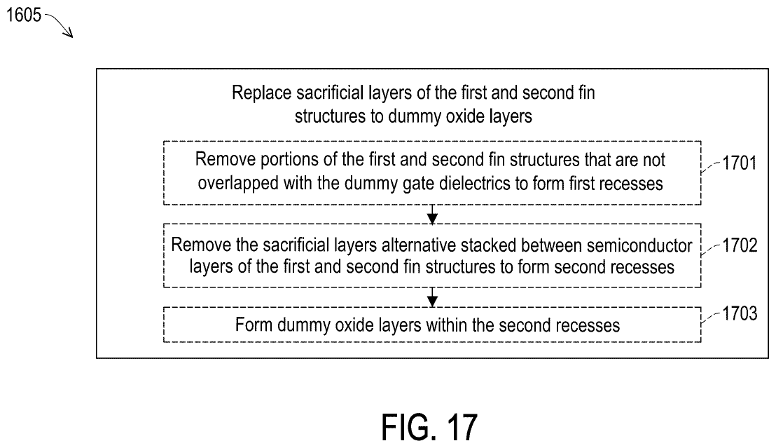

Referring to FIG. 15, FIG. 15 illustrates the schematic cross-sectional view. In some embodiments, an etch stop layer 75 is formed over the forksheet structure 1400. In some embodiments, the etch stop layer 75 includes silicon nitride, silicon carbide, silicon oxynitride, aluminum oxide, aluminum nitride, or the like, or multilayers thereof. In some embodiments, the etch stop layer 75 is formed through ALD, CVD, PECVD, or the like.

An inter-layer dielectric (ILD) 76 is formed over the etch stop layer 75. In some embodiments, the ILD 76 includes a dielectric material such as silicon oxide, PSG, BSG, BPSG, USG, or the like. In some embodiments, the ILD 76 is formed by FCVD, CVD, PECVD, or the like.

The ILD 76 and the etch stop layer 75 are etched to form openings for subsequently formed gate contact plugs 98. In some embodiments, the openings are formed by any suitable etching process such as a dry etching process or a wet etching process. In some embodiments, the openings are filled with one or more conductive material such as Ti, TiN, W, Co, or the like, and then a planarization process is performed to form the gate contact plugs 98. In some embodiments, the gate contact plugs 98 are in contact with and electrically connected to the gate electrode 62 respectively.

Referring to FIG. 16 to FIG. 17, flowcharts illustrate processing steps of a process for forming a semiconductor device in accordance with some embodiments of the present disclosure.

Referring to step 1601 and FIG. 1 to FIG. 2 and FIG. 16, first and second fin structures 24a, 24b extending in parallel along a first direction are formed over adjacent protruding fins 20′ of a substrate 20 respectively. Shallow trench isolation (STI) regions 26 are formed on the substrate 20 and wrap around the adjacent protruding fins 20′ to physically and electrically separate the adjacent protruding fins 20′. A hard mask layer 28 is formed on the STI regions 26.

Referring to step 1602 and FIG. 3 and FIG. 16, dummy gate dielectrics 32 are formed over the first and second fin structures 24a, 24b and cover sidewalls of the first and second fin structures 24a, 24b.

Referring to step 1604 and FIG. 4A to FIG. 4B and FIG. 16, a dummy gate structure 34 is formed on the dummy gate dielectrics 32, extends along a second direction perpendicular to the first direction, and is across the first and second fin structures 24a, 24b.

Referring to step 1604 and FIG. 4A and FIG. 4B and FIG. 16, parallel gate spacers 38 are formed on opposite sidewalls of the dummy gate structure 34 extending along the second direction.

Referring to step 1605 and FIG. 5A to FIG. 5B and FIG. 16, the first semiconductor layers 22A (referred to as sacrificial layers) (as shown in FIG. 4B) of the first and second fin structures 24a, 24b are replaced to dummy oxide layers 40. Each dummy oxide layer 40 is joined to and in contact with the corresponding dummy gate dielectrics 32. The step 1605 includes the following steps 1701 to 1703 as shown in FIG. 17.

Referring to step 1701 and FIG. 4A to FIG. 5B and FIG. 17, portions of the first and second fin structures 24a, 24b that are not overlapped with the dummy gate dielectrics 32 are removed to form first recesses (not shown).

Referring to step 1702 and FIG. 4A to FIG. 5B and FIG. 17, the sacrificial layers (as shown in FIG. 4B) alternative stacked between second semiconductor layers 22B of the first and second fin structures 24a, 24b are removed to form second recesses (not shown).

Referring to step 1703 and FIG. 5A to FIG. 5B and FIG. 17, dummy oxide layers 40 are formed within the second recesses. The dummy oxide layers 40 and the second semiconductor layers 22B are alternative and vertically stacked to each other.

Referring to step 1606 and FIG. 5A to FIG. 5B and FIG. 16, source/drain regions 39 are formed within the first recesses, after the dummy oxide layers 40 are formed.

Referring to step 1607 and FIG. 6 and FIG. 16, an opening (e. g a gate cut-opening) O1 is formed in the dummy gate structure 34 and between the first and second fin structures 24a′, 24b′.

Referring to step 1608 and FIG. 7A to FIG. 7B and FIG. 16, portions of the dummy gate dielectrics 32 are removed so that dummy gate structure 34, facing sidewalls (e.g. the inner sidewalls 22I) of the first and second fin structures 24a′, 24b′ and facing sidewalls of the parallel gate spacers 38 are revealed.

Referring to step 1609 and FIG. 8A to FIG. 8B and FIG. 16, protection layers 42 are formed on the facing sidewalls of the first and second fin structures 24a′, 24b′ within the opening O2 and between the parallel gate spacers 38.

Referring to step 1610 and FIG. 9A to FIG. 9C and FIG. 16 a dielectric liner layer 47 is formed to cover the protection layers 42 and the facing sidewalls of the parallel gate spacers 38 within the opening O2, and a dielectric material fills within the opening O2 to form a dielectric block 49 enclosed by the dielectric liner layer 47.

Referring to step 1611 and FIG. 10 and FIG. 16, the dummy gate structure 34 is removed.

Referring to step 1612 and FIG. 11A to FIG. 11B and FIG. 16, the dummy gate dielectrics 32, the dummy oxide layers 40, portions of the dielectric liner layer 47 and portions of the dielectric blocks 49 are removed to reveal outer sidewalls (e.g. the outer sidewalls 22O) of the first and second fin structures 24a″, 24b″ and reveal top surfaces 221 and bottom surfaces 222 of the second semiconductor layers 22B.

Referring to step 1613 and FIG. 12A to FIG. 12B and FIG. 16, the protection layers 42 are removed to form recesses 58 and reveal the facing sidewalls (e.g. the inner sidewalls 22I) of the first and second fin structures 24a″, 24b″.

Referring to step 1614 and FIG. 13A to FIG. 13C and FIG. 16, a separation structure 50 is formed by removing portions of the dielectric liner layer 47 to widen the recesses 58.

Referring to step 1615 and FIG. 14A to FIG. 14C and FIG. 16, a first gate electrode 621 and a second gate electrode 622 are formed in the widened recesses 58 and on the first and second fin structures 24a″, 24b″ respectively. The separation structure 50 physically and electrically separates the first gate electrode 621 and the second gate electrode 622.

Referring to step 1616 and FIG. 15 and FIG. 16, gate contact plugs 98 (only one gate contact plug is shown in FIG. 15) are formed on and electrically connected to the first gate electrode 621 and the second gate electrode 622 respectively.

A semiconductor device and a method of forming the semiconductor device are provided. A dummy gate dielectric sandwiched between gate spacers is formed on inner and outer sidewalls of first and second fin structures. An opening is formed to reveals the inner sidewalls (e.g. the facing sidewalls) of first and second fin structures. Protection layers are formed on the facing sidewalls of the first and second fin structure and sandwiched between the gate spacers. A dielectric liner layer is formed on the protection layer and the gate spacers. A dielectric block is formed within the opening and enclosed by the dielectric liner layer. Due to the material differences, the dummy gate dielectric and the protection layer are removed by different etching steps to form recesses revealing the facing sidewalls of the first and second fin structures. A separation structure is formed by removing portions of the dielectric liner layer to widen the recesses. First and second gate electrodes are formed in the widened recesses and on the first and second fin structures respectively. The separation structure physically and electrically separates the first gate electrode and the second gate electrode.

The facing sidewalls of the first and second fin structures protected by the protection layer remain a greater lateral dimension of the dielectric liner layer on the gate spacers in the subsequent processes, relative to the inner sidewalls not covered by the protection layer (e.g. covered by the dummy gate dielectric). The semiconductor device including the separation structure with the greater lateral dimension improves the gate control performance, the switch speed and improve alternating current (AC) performance. The semiconductor device also improves the controllability of the silicon (channel) sheet formation of the first and second fin structures. As a result, the performance of the semiconductor device is improved.

In accordance with some embodiments of the disclosure, a method of forming a semiconductor device is provided. A first fin structure and a second fin structure are formed and extend in parallel along a first direction. Dummy gate dielectrics are formed over the first and second fin structures and cover sidewalls of the first and second fin structures. A dummy gate structure is formed on the dummy gate dielectrics, extends along a second direction perpendicular to the first direction, and is across the first and second fin structures. Parallel gate spacers are formed on opposite sidewalls of the dummy gate structure and extend along the second direction. An opening is formed in the dummy gate structure and between the first and second fin structures. Portions of the dummy gate dielectrics are removed so that the dummy gate structure, facing sidewalls of the first and second fin structures and facing sidewalls of the parallel gate spacers are revealed. Protection layers are formed on the facing sidewalls of the first and second fin structures within the opening and between the parallel gate spacers. A dielectric liner layer is formed to cover the protection layers and the facing sidewalls of the parallel gate spacers within the opening. A dielectric material fills within the opening to form a dielectric block enclosed by the dielectric liner layer. The dummy gate structure and the dummy gate dielectrics are removed to reveal outer sidewalls of the first and second fin structures. The protection layers are removed to form recesses and reveal the facing sidewalls of the first and second fin structures. A separation structure is formed by removing portions of the dielectric liner layer to widen the recesses. A first gate electrode and a second gate electrode are formed in the widened recesses and on the first and second fin structures respectively. The separation structure physically and electrically separates the first gate electrode and the second gate electrode.

In accordance with some embodiments of the disclosure, a method of forming a semiconductor device is provided. A first fin structure and a second fin structure are formed over adjacent protruding fins of a substrate respectively. A shallow trench isolation (STI) region is formed, and physically and electrically separates the adjacent protruding fins. Dummy gate dielectrics are formed over the first and second fin structures and cover sidewalls of the first and second fin structures. A dummy gate structure is formed on the dummy gate dielectrics. An opening is formed between the first and second fin structures. Portions of the dummy gate dielectrics are removed so that the dummy gate structure, the STI region and facing sidewalls of the first and second fin structures are revealed. Protection layers are formed on the facing sidewalls of the first and second fin structures. A dielectric liner layer is formed to cover the protection layers within the opening. A dielectric material fills within the opening to form a dielectric block enclosed by the dielectric liner layer. The dummy gate structure and the dummy gate dielectrics are removed to reveal outer sidewalls of the first and second fin structures. The protection layers are removed to form recesses and reveal the facing sidewalls of the first and second fin structures. A separation structure is formed by removing portions of the dielectric liner layer to widen the recesses. A first gate electrode and a second gate electrode is formed in the widened recesses and on the first and second fin structures respectively. The separation structure physically and electrically separates the first gate electrode and the second gate electrode.

In accordance with some embodiments of the disclosure, a semiconductor device is provided. The semiconductor device includes a first fin structure and a second fin structure, a first gate electrode and a second gate electrode, a separation structure, and gate spacers. The first fin structure and the second fin structure extend in parallel along a first direction. The first gate electrode extends along a second direction perpendicular to the first direction and is across the first fin structure. The second gate electrode extends along the second direction and is across the second fin structure. The separation structure is disposed between the first and second fin structures and between the first gate electrode and the second gate electrode. The separation structure physically and electrically separates the first gate electrode and the second gate electrode. The gate spacers extend along the second direction and are disposed on opposite sidewalls of the first gate electrode, on opposite sidewalls of the second gate electrode and on opposite sidewalls of the separation structure. The separation structure includes a dielectric block and a dielectric liner layer. The dielectric block includes a first sidewall, a second sidewall opposite to the first sidewall, and a bottom surface connecting the first and second sidewalls. The dielectric liner layer extends from the first sidewall, along the bottom surface to the second sidewall of the dielectric block.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a first fin structure and a second fin structure extending in parallel along a first direction;
forming dummy gate dielectrics over the first and second fin structures and covering sidewalls of the first and second fin structures;
forming a dummy gate structure on the dummy gate dielectrics, extending along a second direction perpendicular to the first direction, and across the first and second fin structures;
forming parallel gate spacers on opposite sidewalls of the dummy gate structure extending along the second direction;
forming an opening in the dummy gate structure and between the first and second fin structures, and removing portions of the dummy gate dielectrics so that the dummy gate structure, facing sidewalls of the first and second fin structures and facing sidewalls of the parallel gate spacers are revealed;
forming protection layers on the facing sidewalls of the first and second fin structures within the opening and between the parallel gate spacers;
forming a dielectric liner layer to cover the protection layers and the facing sidewalls of the parallel gate spacers within the opening;
forming a dielectric material filling within the opening to form a dielectric block enclosed by the dielectric liner layer;
removing the dummy gate structure and the dummy gate dielectrics to reveal outer sidewalls of the first and second fin structures;
removing the protection layers to form recesses and reveal the facing sidewalls of the first and second fin structures;
forming a separation structure by removing portions of the dielectric liner layer to widen the recesses; and
forming a first gate electrode and a second gate electrode in the widened recesses and on the first and second fin structures respectively, wherein the separation structure physically and electrically separates the first gate electrode and the second gate electrode.

2. The method of claim 1, wherein the protection layers are formed selectively on the revealed dummy gate structure and the revealed facing sidewalls of the first and second fin structures.

3. The method of claim 1, wherein forming the protection layers comprises:
performing a deposition process using at least one precursor selected from silane (SiH₄), chlorosilane (SiH₃Cl), dichlorosilane (SiH₂Cl₂), trichlorosilane (SiHCl₃), silicon chloride (SiCl₄), germane (GeH₄), germanium tetrachloride (GeCl₄), or a combination thereof, and removing the protection layers comprises:
performing an etching process using at least an etchant selected from fluorine and ammonia.

4. The method of claim 1, wherein each one of the first and second fin structures comprises sacrificial layers and semiconductor layers vertically and alternately stacked to each other, and
wherein forming the first and second fin structures comprises:
replacing the sacrificial layers of the first and second fin structures to dummy oxide layers, wherein each dummy oxide layer is joined to and in contact with the corresponding dummy gate dielectrics.

5. The method of claim 4, wherein removing the portions of the dummy gate dielectrics comprises revealing facing sidewalls of the dummy gate dielectrics and facing sidewalls of the dummy oxide layers, and
the method further comprises: performing a lateral etching process to remove portions of the dummy oxide layers and the dummy gate dielectrics so that the facing sidewalls of the dummy oxide layers and the dummy gate dielectrics are laterally recessed.

6. The method of claim 5, wherein forming the protection layers comprises:
forming the protection layers on the facing sidewalls the first and second fin structures, the dummy oxide layers and the dummy gate dielectrics.

7. The method of claim 4, wherein replacing the sacrificial layer of the first and second fin structures to the dummy oxide layers comprises;
removing portions of the first and second fin structures that are not overlapped with the dummy gate dielectrics to form first recesses;
removing the sacrificial layers the first and second fin structures to form second recesses between the semiconductor layers; and
forming the dummy oxide layers within the second recesses.

8. The method of claim 7, the method further comprises:
forming source/drain regions within the first recesses, after the dummy oxide layers are formed.

9. The method of claim 1, wherein in the separation structure, lateral dimension of the dielectric liner layer in the second direction is smaller than a lateral dimension of the dielectric block in the second direction.

10. A method for forming a semiconductor device, comprising:
forming a first fin structure and a second fin structure over adjacent protruding fins of a substrate respectively;
forming a shallow trench isolation (STI) region physically and electrically separating the adjacent protruding fins;
forming dummy gate dielectrics over the first and second fin structures and covering sidewalls of the first and second fin structures;
forming a dummy gate structure on the dummy gate dielectrics;
forming an opening between the first and second fin structures, and removing portions of the dummy gate dielectrics so that the dummy gate structure, the STI region and facing sidewalls of the first and second fin structures are revealed;
forming protection layers on the facing sidewalls of the first and second fin structures;
forming a dielectric liner layer to cover the protection layers within the opening;
filling a dielectric material within the opening to form a dielectric block enclosed by the dielectric liner layer;
removing the dummy gate structure and the dummy gate dielectrics to reveal outer sidewalls of the first and second fin structures;
removing the protection layers to form recesses and reveal the facing sidewalls of the first and second fin structures;
forming a separation structure by removing portions of the dielectric liner layer to widen the recesses;
forming a first gate electrode and a second gate electrode in the widened recesses and on the first and second fin structures respectively, wherein the separation structure physically and electrically separates the first gate electrode and the second gate electrode.

11. The method of claim 10, wherein the protection layers are formed selectively on the revealed dummy gate structure and the revealed facing sidewalls of the first and second fin structures.

12. The method of claim 10, wherein forming the protection layers comprises:
performing a deposition process using at least one precursor selected from silane (SiH₄), chlorosilane (SiH₃Cl), dichlorosilane (SiH₂Cl₂), trichlorosilane (SiHCl₃), silicon chloride (SiCl₄), germane (GeH₄), germanium tetrachloride (GeCl₄), or a combination thereof, and wherein removing the protection layers comprises:
performing an etching process using at least an etchant selected from fluorine and ammonia.

13. The method of claim 10, wherein each one of the first and second fin structures comprises sacrificial layers and semiconductor layers vertically and alternately stacked to each other, and
wherein forming the first and second fin structures comprises:
replacing the sacrificial layers of the first and second fin structures to dummy oxide layers, wherein each dummy oxide layer is joined to and in contact with the corresponding dummy gate dielectrics.

14. The method of claim 13, wherein removing the portions of the dummy gate dielectrics comprises revealing facing sidewalls of the dummy gate dielectrics and facing sidewalls of the dummy oxide layers, and
the method further comprises: performing a lateral etching process to remove portions of the dummy oxide layers and the dummy gate dielectrics so that the facing sidewalls of the dummy oxide layers and the dummy gate dielectrics are laterally recessed.

15. A semiconductor device, comprising:
a first fin structure and a second fin structure extending in parallel along a first direction;
a first gate electrode, extending along a second direction perpendicular to the first direction and across the first fin structure;
a second gate electrode extending along the second direction and across the second fin structure;
a separation structure disposed between the first and second fin structures and between the first gate electrode and the second gate electrode, wherein the separation structure physically and electrically separates the first gate electrode and the second gate electrode; and
gate spacers, extending along the second direction and disposed on opposite sidewalls of the first gate electrode, on opposite sidewalls of the second gate electrode and on opposite sidewalls of the separation structure,
wherein the separation structure comprises:
a dielectric block comprising a first sidewall, a second sidewall opposite to the first sidewall, and a bottom surface connecting the first and second sidewalls, and
a dielectric liner layer extending from the first sidewall, along the bottom surface to the second sidewall of the dielectric block.

16. The semiconductor device of claim 15, wherein a lateral dimension of the dielectric liner layer in the second direction is smaller than a lateral dimension of the dielectric block in the second direction, and a ratio of the lateral dimension of the dielectric block to the lateral dimension of the dielectric liner layer ranges from about 1:0.75 to about 1:0.98.

17. The semiconductor device of claim 15, wherein the first gate electrode comprises:
a base portion sandwiched between the first fin structure and the dielectric block, and
a protrusion protruding from the base portion to in contact with the dielectric liner layer, and sandwiched between the dielectric block and one of the gate spacers.

18. The semiconductor device of claim 15, wherein the dielectric block comprises:
a lower portion disposed between the first and second fin structures, and
an upper portion extending from the lower portion and above the first and second fin structures,
wherein a lateral dimension of the lower portion in the second direction is greater than a lateral dimension of the upper portion in the second direction.

19. The semiconductor device of claim 18, wherein the dielectric liner layer comprises:
a lower portion disposed on the bottom surface of the dielectric block,
a middle portion extending from the lower portion and disposed on the lower portion of the dielectric block, and
an upper portion protruding from the middle portion and disposed on the upper portion of the dielectric block,
wherein a lateral dimension of the middle portion in the second direction is greater than lateral dimensions of the upper portion and the lower portion in the second direction.

20. The semiconductor device of claim 19, wherein the lateral dimension of the middle portion of the dielectric liner layer is smaller than the lateral dimension of the lower portion of the dielectric block.
